(19) United States
(12) Patent Application Publication
(10) Pub. No.: US 2010/0307800 A1
(43) Pub. Date: Dec. 9, 2010

(54) Anodised Aluminum, Dielectric, and Method

(75) Inventors: Kai Fook Francis Wee, Singapore (SG); Jian Hua Xu, Zhuhai (CN); Jian Hong Dai, Zhuhai (CN)

Correspondence Address: INTELLECTUAL PROPERTY LAW GROUP LLP, 12 SOUTH FIRST STREET, SUITE 1205, SAN JOSE, CA, 95113, US

(73) Assignee: OPULENT ELECTRONICS INTERNATIONAL PTE LTD, SINGAPORE (SG)

(21) Appl. No.: 12/278,968

(22) PCT Filed: Feb. 10, 2006
(86) PCT No.: PCT/SG2006/000025

§ 371 Date: Aug. 8, 2008

(51) Int. Cl. H05K 1/09; B32B 15/04; C25D 11/06; C25D 5/50; H05K 1/03

(52) U.S. Cl. 174/257; 205/50; 205/326; 205/224; 174/258

(57) ABSTRACT

The invention provides an anodised aluminium product for use in a metal core printed circuit board which in which the anodised layer forms a dielectric, and the resultant metal core printed circuit board has a sandwich structure having a thermal conductivity higher than and a thermal resistance lower than conventional metal core printed circuit boards using alternative dielectric layers, and with improved electrical insulation properties. The invention has application in manufacture of rigid and flexible printed circuit boards which have a metal substrate, manufacture of a heat conductive substrate for semiconductor devices, and electronic devices. While the use of the invention is described in relation to metal core printed circuit boards, the anodising process and anodised aluminium of the invention may have other applications beyond this technology. The invention also provides a method of manufacturing such an anodised aluminium product.

### FIELD OF THE INVENTION

This invention relates to anodised aluminium, an anodised aluminium dielectric, and method for fabricating the same. In particular this invention relates to a dielectric having application in electronics, in particular where there is a requirement to dissipate large amounts of heat, however, the anodised aluminium of the invention may have other applications.

### BACKGROUND ART

As the electronics industry has continued to evolve, there has been an impressive increase in performance of electronic devices such as CPUs for computers, and also a reduction in size of such devices. In the field of opto-electronics, in particular, the development light emitting diode based devices to replace traditional thermo-incandescent light globes, there has also been an increase in performance of these devices.

Such increase in performance has come at the expense of increased heat generated by such devices, which heat must be dissipated, if these devices are to function reliably. Current dielectric solutions for insulated metal substrates have possibly reached their upper limits in terms of heat dissipation. The parameter used to determine this property is thermal conductivity, W/mK (W·m⁻¹·K⁻¹). The upper limit value of existing dielectric materials, which often uses a combination of epoxy glass fillers, ceramic fillers, and many other types of thermal conductive fillers is probably from 4 W/mK to 6 W/mK.

It is an object of this invention to provide an improved dielectric which is capable of achieving thermal conductivity beyond 4 W/mK to 6 W/mK.

Throughout the specification, unless the context requires otherwise, the word “comprise” or variations such as “comprises” or “comprising”, will be understood to imply the inclusion of a stated integer or group of integers but not the exclusion of any other integer or group of integers. Note also that throughout this specification, that all references made to weight of reagents are for the weight of the compound referred to, excluding any water of crystallisation, where present.

### DISCLOSURE OF THE INVENTION

In accordance with the invention there is provided anodised aluminium having an anodised aluminium layer on the surface thereof, said anodised aluminium layer being characterised by having a thickness of at least 10 micron (0.01 mm), and being characterised by having a substantially uniform crystalline structure.

Further, in accordance with the invention there is provided an aluminium substrate having an anodised aluminium dielectric layer on at least one surface thereof, said anodised aluminium layer being characterised by having a thickness of at least 10 micron (0.01 mm), and being characterised by having a substantially uniform crystalline structure.

Still further, in accordance with the invention there is provided a metal core printed circuit board having an aluminium substrate and an anodised aluminium dielectric layer on at least one surface thereof, each said anodised aluminium layer being characterised by having a thickness of at least 10 micron (0.01 mm), and being characterised by having a substantially uniform crystalline structure.

Preferably said anodised layer is formed by electrolysis, the electrolysis being carried out with an electrode potential difference of 100 volts or greater.

Preferably said electrolysis takes place in an alkaline electrolyte.

Also in accordance with the invention there is provided anodised aluminium having an anodised aluminium layer on the surface thereof, said anodised aluminium layer being characterised by having a thickness of at least 10 micron (0.01 mm), and being characterised by being formed by electrolysis in an alkaline electrolyte, the electrolysis being carried out with an electrode potential difference of 100 volts or greater.

Further, in accordance with the invention there is provided an aluminium substrate having an anodised aluminium dielectric layer on at least one surface thereof, said anodised aluminium layer being characterised by having a thickness of at least 10 micron (0.01 mm), and being characterised by being formed in an alkaline electrolyte, the electrolysis being carried out with an electrode potential difference of 100 volts or greater.

Still further, in accordance with the invention there is provided a metal core printed circuit board having an aluminium substrate and an anodised aluminium dielectric layer on at least one surface thereof, each said anodised aluminium layer being characterised by having a thickness of at least 10 micron (0.01 mm), and being characterised by being formed in an alkaline electrolyte, the electrolysis being carried out with an electrode potential difference of 100 volts or greater.

The anodised layer is also characterised by being able to withstand more acid and alkaline conditions than a normal anodised layer in anodised aluminium. The anodised layer of the invention has properties more akin to a ceramic than hitherto known anodised aluminium layers.

Preferably said alkaline electrolyte includes an alkali metal silicate.

Preferably said aluminium substrate comprises a sheet material having a thickness from 0.25 to 6 mm.

Preferably said aluminium substrate comprises a sheet material having a thickness from 0.4 to 4.5 mm.

Preferably said aluminium substrate comprises a sheet material having a thickness from 0.8 to 3.2 mm.

Preferably said anodised layer has a thickness of from 10 to 300 micron.

Preferably said anodised layer has a dielectric breakdown voltage of from 500 volts, up to 2000 volts.

Preferably said anodised layer has a dielectric breakdown voltage of at least 1000 volts.

Preferably said anodised layer has a dielectric breakdown voltage of at least 1200 volts.

Preferably said anodised layer has a dielectric breakdown voltage of at least 1300 volts.

Preferably said anodised layer has a dielectric breakdown voltage of at least 1500 volts.

Preferably said aluminium substrate and said anodised layer together have a thermal conductivity of greater than from 4 W/mK to 6 W/mK.

Preferably said aluminium substrate and said anodised layer together have a thermal conductivity of greater than 20 W/mK.

Preferably said aluminium substrate and said anodised layer together have a thermal resistance of from 0.020° C.in²/W to 0.050° C.in²/W.

Preferably said aluminium substrate and said anodised layer together have a thermal resistance of from 0.030° C.in²/W to 0.050° C.in²/W.

Preferably the electrolysis is carried out with said electrode potential difference of between 150 volts and 600 volts.

Preferably the electrolysis is carried out with said electrode potential difference of between 200 volts and 500 volts.

Preferably the electrolysis is carried out with said electrode potential difference of between 300 volts and 450 volts.

Preferably the current drawn during the electrolysis is up to 40 amperes/dm².

Preferably the current drawn during the electrolysis is up to 30 amperes/dm².

Preferably the current drawn during the electrolysis is up to 20 amperes/dm²

Preferably the peak current drawn during the electrolysis is from 15 amperes/dm² to 20 amperes/dm².

Preferably the minimum current drawn during the electrolysis is about 0.5 amperes/dm².

Preferably the minimum current drawn during the electrolysis is about 0.8 amperes/dm².

Preferably the minimum current drawn during the electrolysis is about one ampere/dm².

Preferably after anodising, the anodised aluminium is subject to a hydration step, followed by a baking step. This is believed to minimise pin-hole formation in the dielectric layer.

Preferably the hydration step is carried out in water at a temperature of from 90° C. to 100° C. for a period of at least 5 minutes.

Preferably the hydration step is carried out at a temperature of from 95° C. to 100° C.

Preferably the hydration step is carried out at a temperature of 98° C.±2° C.

Preferably the hydration step is carried out for a period of at least 10 minutes.

Preferably the hydration step is carried out for a period of at least 15 minutes.

Preferably the hydration step is carried out for a period of 20 minutes±1 minute. While a greater period would also be effective, it should not prove necessary.

Preferably the baking step is carried out at a temperature of at least 150° C. to 250° C.

Preferably the baking step is carried out at a temperature of from 200° C. to 300° C.

Preferably the baking step is carried out at a temperature of 220° C.±5° C.

Preferably the baking step is carried out for a period of at least 30 minutes.

Preferably the baking step is carried out for a period of at least 50 minutes.

Preferably the baking step is carried out for a period of from 60 minutes to 70 minutes. Again, while a greater period of time would prove successful, this should not be necessary.

Preferably said metal core printed circuit board includes a copper layer bonded to said anodised layer. The copper layer may comprise a copper foil bonded to the anodised layer using a thin film of adhesive. Using such a technique should provide a thermal conductivity in the completed structure of from 4 W/mK to 20 W/mK.

Alternatively a copper layer can be formed on the anodised layer using a plasma deposition technique, in which case thermal conductivity in the completed structure of from 26 W/mK to 40 W/mK can be achieved.

Preferably said metal core printed circuit board includes a said anodised layer on each (opposed) surface thereof.

Also in accordance with the present invention there is provided a method of manufacturing an anodised aluminium material comprising providing an aluminium material, forming an anodised layer thereon on at least one surface of said aluminium material, said anodised layer being characterised by having a substantially uniform crystalline structure.

Also in accordance with the present invention there is provided a method of manufacturing an anodised aluminium material comprising providing an aluminium material, forming an anodised layer thereon on at least one surface of said aluminium material, said method being characterised by the electrolysis being carried out with an electrode potential difference of 100 volts or greater.

Preferably the aluminium substrate is anodised in an alkaline electrolyte.

The anodised layer is characterised by possessing superior dielectric properties to conventional acid electrolyte anodised aluminium.

The anodised layer is also characterised by being able to withstand more acid and alkaline conditions than a normal anodised layer in anodised aluminium.

Preferably the alkaline electrolyte includes an alkali metal silicate.

Preferably the anodising is carried out at a temperature of from 20° C. to 50° C.

Preferably the electrolysis is carried out with said electrode potential difference of between 150 volts and 600 volts.

Preferably the electrolysis is carried out with said electrode potential difference of between 200 volts and 500 volts.

Preferably the electrolysis is carried out with said electrode potential difference of between 300 volts and 450 volts.

Preferably the current drawn during the electrolysis is up to 40 amperes/dm².

Preferably the current drawn during the electrolysis is up to 30 amperes/dm².

Preferably the current drawn during the electrolysis is up to 20 amperes/dm²

Preferably the peak current drawn during the electrolysis is from 15 amperes/dm² to 20 amperes/dm².

Preferably the minimum current drawn during the electrolysis is about 0.5 amperes/dm².

Preferably the minimum current drawn during the electrolysis is about 0.8 amperes/dm².

Preferably the minimum current drawn during the electrolysis is about one ampere/dm².

In one arrangement, preferably the electrolyte has the following constituents:
5 g/litre to 10 g/litre K₂SiO₃
4 g/litre to 6 g/litre Na₂O₂
0.5 g/litre to 1 g/litre NaF
1 g/litre to 3 g/litre Na₃VO₃
2 g/litre to 3 g/litre CH₃COONa.

Preferably the electrolyte has a pH of from 11 to 13.

Preferably the anodising proceeds by increasing the voltage to 300V and holding the voltage at this level for from 5 to 15 seconds, and then increasing the voltage to 450V and maintaining this voltage for a period of from 5 to 10 minutes.

Preferably the power dissipated during the electrolysis peaks at between 15 A/dm² to 20 A/dm², and falls as the anodising proceeds.

In an alternative arrangement, preferably the anodising proceeds in a plurality of stages, where in a first stage the electrolyte includes about (reckoned as anhydrous) 200 g/litre (±10%) K₂O.nSiO₂ where 0.5≦n≦3.5, and in a second stage the electrolyte includes 70 g/litre (±10%) Na₄P₂O₇.

Preferably n lies in the range from 1 to 3.5.

Preferably n lies in the range from 1.5 to 3.5.

Preferably n lies in the range from 2 to 3.

At higher values of n, it may be necessary to carry out the anodising at higher than atmospheric pressure, in order for the K₂O.nSiO₂ to go into solution.

Preferably, in the first stage the current is maintained stabilised at about 1 A/dm².

Preferably, in the first stage the current is maintained at about 1 A/dm² for about five minutes.

Preferably, in the second stage the current is maintained stabilised at about 1 A/dm².

Preferably, in the second stage the current is maintained at about 1 A/dm² for about 15 minutes.

Following the anodising process the aluminium is washed in deionised water, after which it can be used in manufacture.

Preferably after anodising, the anodised aluminium is subject to a hydration step, followed by a baking step. This is believed to minimise the incidence of pin-holes formed in the dielectric layer.

Preferably the hydration step is carried out in water at a temperature of from 90° C. to 100° C. for a period of at least 5 minutes.

Preferably the hydration step is carried out at a temperature of from 95° C. to 100° C.

Preferably the hydration step is carried out at a temperature of 98° C.±2° C.

Preferably the hydration step is carried out for a period of at least 10 minutes.

Preferably the hydration step is carried out for a period of at least 15 minutes.

Preferably the hydration step is carried out for a period of 20 minutes±1 minute. While a greater period would also be effective, it should not prove necessary.

Preferably the baking step is carried out at a temperature of at least 150° C. to 250° C.

Preferably the baking step is carried out at a temperature of from 200° C. to 300° C.

Preferably the baking step is carried out at a temperature of 220° C.±5° C.

Preferably the baking step is carried out for a period of at least 20 minutes.

Preferably the baking step is carried out for a period of at least 30 minutes.

Preferably the baking step is carried out for a period of at least 50 minutes.

Preferably the baking step is carried out for a period of from 60 minutes to 70 minutes. Again, while a greater period of time would prove successful, this should not be necessary.

The invention provides an anodised aluminium product for use in a metal core printed circuit board which in which the anodised layer forms a dielectric, and the resultant metal core printed circuit board has a sandwich structure having a thermal conductivity higher than and a thermal resistance lower than conventional metal core printed circuit boards using alternative dielectric layers, and with improved electrical insulation properties. The invention has application in manufacture of rigid and flexible printed circuit boards which have a metal substrate, manufacture of a heat conductive substrate for semiconductor devices, and electronic devices. While the use of the invention is described in relation to metal core printed circuit boards, the anodising process and anodised aluminium of the invention may have other applications beyond this technology.

### BEST MODE(S) FOR CARRYING OUT THE INVENTION

Several preferred embodiments of the invention will now be described in the following description, in which two preferred techniques for preparing an anodised dielectric material will also be described.

An anodised aluminium dielectric is prepared on an aluminium substrate, in accordance with the following method. The aluminium substrate, which typically will be a sheet of aluminium, is degreased in a degreasing solution at a temperature of 60° C.±20° C. for a period of from one to three minutes. The degreasing solution is a 5% to 25% (by volume) aqueous solution of sulphuric acid into which chromium anhydride has been added in the order of 2% to 10% by weight.

This is followed with a water wash at room temperature, and drying in hot air at a temperature of 65° C.±15° C. The water wash and drying step can be performed on a conveyor running at a speed of from 1 to 5 metres per minute.

The aluminium substrate then proceeds to the anodising step. Anodising is performed under alkaline conditions at a temperature of between 20° C. and 50° C.

There are two equally preferred methods of anodising, with the first method comprising a single stage comprising electrolysis using a stainless steel cathode in an aqueous electrolyte comprising 10 g/litre K₂SiO₃, 6 g/litre Na₂O₂, 1 g/litre NaF, 3 g/litre Na₃VO₃, and 3 g/litre CH₃COONa. The aluminium substrate is connected as the anode, and the voltage across the anode and cathode is raised to 300 volts and held at this level for ten seconds, before being raised to 450 volts where it is held for ten minutes. After this, the aluminium is removed from the electrolysis bath and washed in deionised water.

The second method of anodising uses a two stage process with the first stage using an aqueous electrolyte comprising 200 g/litre K₂O.nSiO₂ where 0.5≦n≦3.5, under electrolysis for 5 minutes at a voltage sufficient to maintain 1 A/dm² followed by washing, and then a second stage using an aqueous electrolyte comprising 70 g/litre Na₄P₂O₇ under electrolysis for 15 minutes at a voltage sufficient to maintain 1 A/dm². After this, the aluminium is removed from the electrolysis bath and washed in deionised water.

The anodised aluminium is then subjected to a hydrolysis step in a water bath at a temperature of 98° C.±2° C. for a period of 20 minutes, followed by a drying step carried out at 220° C. for 60 to 70 minutes.

The anodised aluminium may form a substrate for a metal core printed circuit board. If this is the case, the aluminium substrate would be anodised as described above, on both sides. Copper can be deposited on both sides using one of a number of known plasma deposition techniques. Where the metal core printed circuit board is to have plated through holes the aluminium substrate would be drilled prior to anodising taking place.

Copper may be adhered using a thin film of adhesive applied by roller or by screen printing. Suitable adhesives include epoxy polyimide glue systems, or any other bonding agents as used in FR4 and other conventional printed circuit board technologies. Where the metal core printed circuit board is to have plated through holes the adhesive provides an insulating layer between the copper layer and the aluminium substrate.

The anodised aluminium of the invention exhibits improved properties compared with hitherto known anodised aluminium which is anodised in an acidic electrolyte. The following table sets out a comparison of properties of the anodised aluminium of the invention compared with known anodised aluminium which is anodised in an acidic electrolyte:

| Properties | Invention | Prior Art Acid Electrolyte |
|---|---|---|
| Maximum thickness (um) | 300 | 50-80 |
| Micro-hardness (HV) | 1500-2500 | 300-500 |
| Dielectric Breakdown | 2000 | 1000-1200 |
| Voltage (Volt) | | |
| Symmetrical | Uniformity on both surface and | Will have sharp defected |
| | internal | edges |
| Pin Hole Rate (%) | <2 | 14-20 |
| Wearable Property | Abrasion rate 10⁻⁷ mm³/Nm | Abrasion rate 10⁻⁶ mm³/Nm |
| Thermal Shock | Temp 300° C. water quench, no | Temp 300° C. air cool, changes |
| Resistance | changes in 35 cycles | after 6 cycles |
| Thermal Stress | Can withstand 2500° C. of thermal | Can withstand 2000° C. of |
| | stress | thermal stress |

Uses for the metal core printed circuit boards include the manufacture of high intensity light emitting diodes for use in domestic and commercial lighting applications, and any other electronic devices where it is important to dissipate heat rapidly.

It should be appreciated that the scope of the invention is not limited to the particular embodiment described herein.

1. A product comprising anodised aluminium having an anodised aluminium layer on the surface thereof, said anodised aluminium layer being characterised by having a thickness of at least 10 micron (0.01 mm), and being characterised by having a substantially uniform crystalline structure, and wherein said anodised layer is formed by electrolysis, the electrolysis being carried out with an electrode potential difference of 100 volts or greater; and wherein said electrolysis takes place in an alkaline electrolyte.

2. A product comprising an aluminium substrate having an anodised aluminium dielectric layer on at least one surface thereof, said anodised aluminium layer being characterised by having a thickness of at least 10 micron (0.01 mm), and being characterised by having a substantially uniform crystalline structure, and wherein said anodised layer is formed by electrolysis, the electrolysis being carried out with an electrode potential difference of 100 volts or greater; and wherein said electrolysis takes place in an alkaline electrolyte.

3. A product comprising a metal core printed circuit board having an aluminium substrate and an anodised aluminium dielectric layer on at least one surface thereof, each said anodised aluminium layer being characterised by having a thickness of at least 10 micron (0.01 mm), and being characterised by having a substantially uniform crystalline structure, and wherein said anodised layer is formed by electrolysis, the electrolysis being carried out with an electrode potential difference of 100 volts or greater; and wherein said electrolysis takes place in an alkaline electrolyte.

4. (canceled)

5. (canceled)

6. A product comprising anodised aluminium having an anodised aluminium layer on the surface thereof, said anodised aluminium layer being characterised by having a thickness of at least 10 micron (0.01 mm), and being characterised by being formed by electrolysis in an alkaline electrolyte, the electrolysis being carried out with an electrode potential difference of 100 volts or greater.

7. A product comprising an aluminium substrate having an anodised aluminium dielectric layer on at least one surface thereof, said anodised aluminium layer being characterised by having a thickness of at least 10 micron (0.01 mm), and being characterised by being formed in an alkaline electrolyte, the electrolysis being carried out with an electrode potential difference of 100 volts or greater.

8. A product comprising a metal core printed circuit board having an aluminium substrate and an anodised aluminium dielectric layer on at least one surface thereof, each said anodised aluminium layer being characterised by having a thickness of at least 10 micron (0.01 mm), and being characterised by being formed in an alkaline electrolyte, the electrolysis being carried out with an electrode potential difference of 100 volts or greater.

9. A product as claimed in any one of the preceding claims wherein said alkaline electrolyte includes an alkali metal silicate.

10. A product as claimed in any one of claims 1-3, or 6-8 wherein said aluminium substrate comprises a sheet material having a thickness from 0.25 to 6 mm.

11. A product as claimed in claim 10 wherein said aluminium substrate comprises a sheet material having a thickness from 0.8 to 3.2 mm.

12. A product as claimed in any one of claims 1-3, or 6-8 wherein said anodised layer has a thickness of from 10 to 300 micron.

13. A product as claimed in any one of claims 1-3, or 6-8 wherein said aluminium substrate and said anodised layer together have a thermal conductivity of greater than from 4 W/mK to 6 W/mK.

14. A product as claimed in any one of claims 1-3, or 6-8 wherein said aluminium substrate and said anodised layer together have a thermal conductivity of greater than 20 W/mK.

15. A product as claimed in any one of claims 1-3, or 6-8 wherein said aluminium substrate and said anodised layer together have a thermal resistance of from 0.020° C.in²/W to 0.050° C.in²/W.

16. A product as claimed in any one of claims 1-3, or 6-8 wherein the electrolysis is carried out with said electrode potential difference of between 150 volts and 600 volts.

17. A product as claimed in any one of claims 1-3, or 6-8 wherein the electrolysis is carried out with said electrode potential difference of between 300 volts and 450 volts.

18. A product as claimed in claim 17 wherein the minimum current drawn during the electrolysis is about one ampere/dm².

19. A product as claimed in any one of claims 1-3, or 6-8 wherein after anodising, the anodised aluminium is subject to a hydration step, followed by a baking step.

20. A product as claimed in claim 19 wherein the hydration step is carried out in water at a temperature of from 90° C. to 100° C. for a period of at least 5 minutes.

21. A product as claimed in claim 20 wherein the baking step is carried out at a temperature of at least 150° C. to 250° C.

22. A product as claimed in claim 3 or claim 8 wherein said metal core printed circuit board includes a copper layer bonded to said anodised layer.

23. A product as claimed in claim 3 or claim 8, wherein a copper layer is formable on the anodised layer using a plasma deposition technique.

24. A product as claimed in claim 22 wherein said metal core printed circuit board includes a said anodised layer on each (opposed) surface thereof.

25. A method of manufacturing an anodised aluminium material comprising providing an aluminium material, forming an anodised layer thereon on at least one surface of said aluminium material, said anodised layer being characterised by having a substantially uniform crystalline structure, and wherein the aluminium substrate is anodised in an alkaline electrolyte.

26. A method of manufacturing an anodised aluminium material comprising providing an aluminium material, forming an anodised layer thereon on at least one surface of said aluminium material, said method being characterised by the electrolysis being carried out with an electrode potential difference of 100 volts or greater, and wherein the aluminium substrate is anodised in an alkaline electrolyte.

27. (canceled)

28. A method as claimed in claim 25 or 26 wherein the alkaline electrolyte includes an alkali metal silicate.

29. A method as claimed in any one of claims 25 and 26 wherein the anodising is carried out at a temperature of from 20° C. to 50° C.

30. A method as claimed in any one of claims 25 and 26 wherein the electrolysis is carried out with said electrode potential difference of between 150 volts and 600 volts.

31. A method as claimed in claim 30 wherein the electrolysis is carried out with said electrode potential difference of between 300 volts and 450 volts.

32. A method as claimed in any one of claims 25 and 26 wherein the electrolyte has the following constituents:
5 g/litre to 10 g/litre K₂SiO₃
4 g/litre to 6 g/litre (calculated as Na₂O) NaOH
0.5 g/litre to 1 g/litre NaF
1 g/litre to 3 g/litre Na₃VO₃
2 g/litre to 3 g/litre CH₃COONa.

33. A method as claimed in claim 32 wherein the anodising proceeds by increasing the voltage to 300V and holding the voltage at this level for from 5 to 15 seconds, and then increasing the voltage to 450V and maintaining this voltage for a period of from 5 to 10 minutes.

34. A method as claimed in any one of claims 25 and 26 wherein the anodising proceeds in a plurality of stages, where in a first stage the electrolyte includes about (reckoned as anhydrous) 200 g/litre (±10%) K₂O.nSiO₂ where 0.5≦n≦3.5, and in a second stage the electrolyte includes 70 g/litre (±10%) Na₄P₂O₇.

35. A method as claimed in claim 34 wherein, in the first stage the current is maintained at about 1 A/dm² for about five minutes.

36. A method as claimed in claim 34 wherein in the second stage the current is maintained at about 1 A/dm² for about 15 minutes.

37. A method as claimed in any one of claims 25 and 26 wherein after anodising, the anodised aluminium is subject to a hydration step, followed by a baking step.

38. A method as claimed in claim 37 wherein the hydration step is carried out in water at a temperature of from 90° C. to 100° C. for a period of at least 5 minutes.

39. A method as claimed in claim 37 wherein the baking step is carried out at a temperature of at least 150° C. to 250° C.

40. (canceled)

41. A product as claimed in claim 23 wherein said metal core printed circuit board includes a said anodised layer on each (opposed) surface thereof.
